(19) United States
(12) Patent Application Publication
(10) Pub. No.: US 2015/0090043 A1
(43) Pub. Date: Apr. 2, 2015

(54) MEMS

(71) Applicant: Infineon Technologies AG, Neubiberg (DE)

(72) Inventors: Guenther Ruhl, Regensburg (DE); Max Christian Lemme, Koeln (DE); Alfons Dehe, Reutlingen (DE); Andreas Fischer, Taeby (SE); Frank Niklaus, Taeby (SE); Anderson Smith, Stockholm (SE)

(21) Appl. No.: 14/497,452

(22) Filed: Sep. 26, 2014

(30) Foreign Application Priority Data
Sep. 27, 2013 (SE) 1300619-2

(51) Int. Cl. G01L 1/18; B81C 1/00; B81B 7/02; G01N 3/02; B81B 3/00

(52) U.S. Cl. CPC G01L 1/18; G01N 3/02; B81B 3/0021; B81B 7/02; B81C 1/00182
USPC 73/777; 29/825

(57) ABSTRACT

Embodiments provide a MEMS including a MEMS device and an detector circuit. The MEMS device includes a membrane, wherein a material of the membrane comprises a band gap and a crystal structure with structural elements (unit cells) connected by covalent bonds in two dimensions only. The detector circuit is configured to determine a deformation of the membrane based on a piezoresistive resistance of the material of the membrane.

### CROSS REFERENCE TO RELATED APPLICATION

This application claims priority to Swedish Patent Application No. 1300619-2 filed Sep. 27, 2013 and is hereby incorporated by reference.

### FIELD

Embodiments of the present invention relate to a MEMS (Microelectromechanical System). Some embodiments relate to a method for manufacturing a MEMS. Some embodiments relate to a MEMS-sensor based on 2D (two dimensional) materials.

### BACKGROUND

Pressure and inertial sensors in MEMS technology commonly have membranes made of silicon. However, the mechanical stability of silicon membranes is limited and prohibits its use for large elongations/deflections, i.e. large pressure differences and accelerations. Further, the sensitivity and thus the signal-to-noise ratio of these sensors is limited by the capacitive measurement principle used for measuring the elongation/deflection of the silicon membrane.

The problem of the limited mechanical stability of the silicon membrane is commonly solved by protective structures, such as ventilation flaps or mechanical stops, which results in a large effort in process management. However, therewith, the problem of the limited functional area with respect to elongations/deflections is not solved. The problem of the limited sensitivity is commonly solved by increasing an area of the membrane, which however leads to a disadvantageous increase of an area of the sensor/component.

### SUMMARY

Embodiments provide a MEMS comprising a MEMS device and an detector circuit. The MEMS device comprises a membrane, wherein a material of the membrane comprises a band gap and a crystal structure with structural elements (unit cells) connected by covalent bonds in two dimensions only. The detector circuit is configured to determine a deformation of the membrane based on a piezoresistive resistance of the material of the membrane.

Further embodiments provide a MEMS comprising a MEMS device and a detector circuit. The MEMS device comprises a membrane and an inertial mass attached to the membrane, wherein a material of the membrane comprises a crystal structure with structural elements (unit cells) connected by covalent in two dimensions only. The detector circuit is configured to determine an acceleration or a rotation rate of the inertial mass based on a piezoresistive resistance of the material of the membrane.

Further embodiments provide a method for manufacturing a MEMS comprising a MEMS device and a detector circuit. The method comprises providing a membrane of the MEMS device, wherein a material of the membrane comprises a band gap and a crystal structure with structural elements connected by covalent bonds in two dimensions only, and providing a detector circuit configured to determine a deformation of the membrane based on a piezoresistive resistance of the material of the membrane.

### BRIEF DESCRIPTION OF THE DRAWINGS

Embodiments of the present invention are described herein making reference to the appended drawings.

FIG. 1 shows a schematic block diagram of a MEMS, according to an embodiment.

FIG. 2a shows in a diagram a change of an energy of the band gap of MoS₂ plotted over an interlayer distance increase of MoS₂ layers.

FIG. 2b shows in a diagram a change of energy of the band gap of MoS₂ plotted over a molybdenum-molybdenum distance variation.

FIG. 3 shows a cross-sectional view of a MEMS device according to an embodiment.

FIG. 4 a cross-sectional view and a top view of a MEMS device with ventilation slots according to an embodiment.

FIG. 5 shows a top view of a MEMS device with two membranes and ventilation slots, and a schematic of the detector circuit, according to an embodiment.

FIG. 6 shows a top view of a MEMS device with a circular-shaped membrane, according to an embodiment.

FIG. 7 shows a MEMS device with an inertial mass attached to the membrane of the MEMS device, according to an embodiment.

FIG. 8a shows a cross-sectional view of a MEMS device with an inertial mass attached to a bottom-side of the membrane of the MEMS device, according to an embodiment.

FIG. 8b shows a top view of the MEMS device shown in FIG. 8a, according to an embodiment.

FIG. 8c shows a cross-sectional view of a MEMS device with an inertial mass attached to a top-side of the membrane of the MEMS device, according to an embodiment.

FIG. 8d shows a top view of the MEMS device shown in FIG. 8c, according to an embodiment.

FIG. 9a shows a cross-sectional view of a MEMS device with ventilation slots and with an inertial mass attached to a bottom-side of the membrane of the MEMS device, according to an embodiment.

FIG. 9b shows a top view of the MEMS device shown in FIG. 8a, according to an embodiment.

FIG. 9c shows a cross-sectional view of a MEMS device with ventilation slots and with an inertial mass attached to a top-side of the membrane of the MEMS device, according to an embodiment.

FIG. 9d shows a top view of the MEMS device shown in FIG. 8c, according to an embodiment.

FIG. 10 shows a top-view of a gyroscopic sensor, according to an embodiment.

FIG. 11 shows a top-view of a tuning fork type gyroscopic sensor, according to an embodiment.

FIG. 12 shows a conceptual design of graphene membrane-based accelerometer, according to an embodiment.

FIG. 13 shows an illustrative view of a material of the membrane, according to an embodiment.

FIG. 14 shows a flowchart of a method for manufacturing a MEMS comprising a MEMS device and a detector circuit, according to an embodiment.

FIGS. 15a-c show cross-sectional views of the MEMS device after different steps of a transfer based manufacturing method.

FIGS. 16a-l show cross-sectional views of the MEMS device after different steps of a direct deposition based manufacturing method.

FIGS. 17a-c show cross-sectional views of the MEMS device after different steps of a direct deposition based manufacturing method.

Equal or equivalent elements or elements with equal or equivalent functionality are denoted in the following description by equal or equivalent reference numerals.

### DETAILED DESCRIPTION

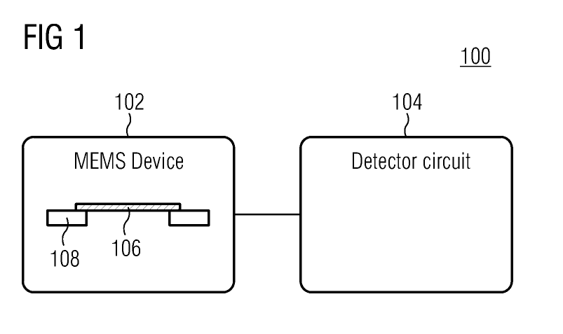

FIG. 1 shows a schematic block diagram of a MEMS (Microelectromechanical System) 100 according to an embodiment. The MEMS 100 comprises a MEMS device 102 and a detector circuit 104. The MEMS device 102 comprises a membrane 106, wherein a material of the membrane 106 comprises a band gap and a crystal structure with structural elements (unit cells) connected by covalent bonds in two dimensions only. The detector circuit 104 is configured to determine a deformation of the membrane based on a piezoresistive resistance of the material of the membrane 106.

In embodiments, the MEMS device 102 can further comprise a support 108 having a cavity there through. The membrane 106 can be arranged on the support 108 such that the membrane 106 extends over the support cavity.

A physical force acting on the membrane 106 may cause a deformation of the membrane 106, e.g., a deflection or elongation of the membrane 106, resulting in a change of a value of the piezoresistive resistance of the membrane material which can be detected by the detector circuit 104.

The afore mentioned problems of common MEMS sensors (limited mechanical stability, limited sensitivity, and limited signal-to-noise ratio) are solved according to embodiments by using a membrane 106 of 2D (two-dimension) material as the central sensor element instead of a membrane of silicon. The mechanical stability of the membrane 106 of 2D material is significantly higher than the stability of a silicon membrane. Thereby, 2D material refers to a material with a crystal structure with structural elements (unit cells) connected by covalent bonds in two dimensions only.

With piezoresistive sensors a high sensitivity (AR/R) is achieved due to the extremely low thickness (h) of the membrane 106 (one to a few atomic-layers) and the large E-module (E):

$$\frac{Δ R}{R} ∝ \sqrt[3]{\frac{{P}^{2} {Ea}^{2}}{{h}^{2}}} \qquad Eq . 1$$

Thereby, a² is an area of the membrane 106 and P is a pressure difference.

Examples of these 2D materials are transition metal chalcogenides, such as MoS₂, WS₂, MoTe₂, MoSe₂, WSe₂, WTe₂, VSe₂, CrS₂, CrSe₂, BP.

Despite having a lower gauge-factor (3 to 4) than silicon (−140 to 200), graphene comprises a significantly higher sensitivity due to the aforementioned reasons. With the gauge-factors of over 200 of transition metal dichalcogenides and similar 2D materials a further, significant improvement of the sensitivity can be achieved. Since the gauge-factor is also influenced by the band gap of the material, here the possibility arises to adapt the gauge-factor by the choice of material:

| Material | Fracture strength | | E-Module | Band gap |
|---|---|---|---|---|
| Si | 2 . . . 3 | GPa | 150 GPa | 1.1 eV |
| Graphene | 130 | GPa | 1000 GPa | 0 eV |
| MoTe₂ | | | | 1.1 eV |
| MoSe₂ | | | | 1.4 eV |
| MoS₂ | 30 | GPa | 330 GPa | 1.8 eV |
| WS₂ | | | | 2.1 eV |

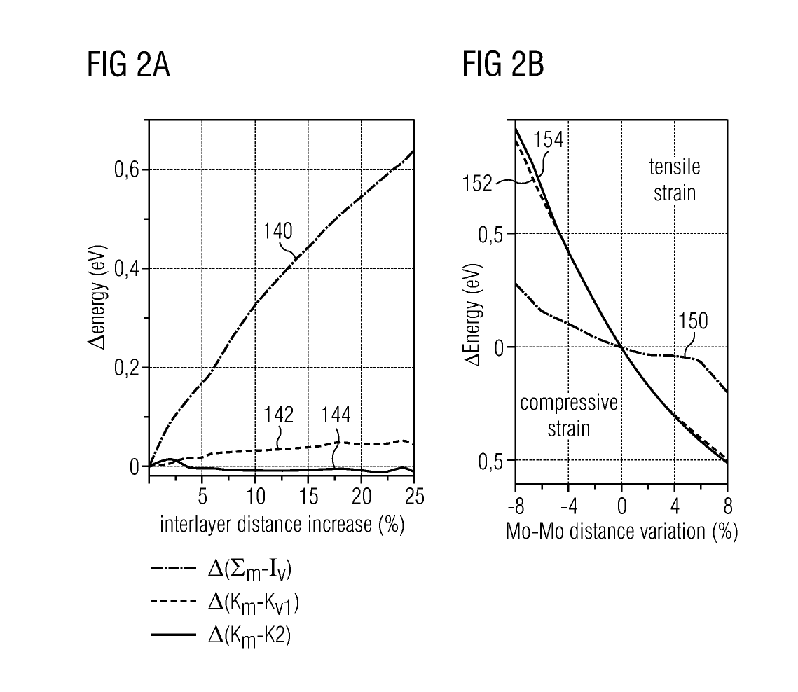

By mechanical stress acting on the membrane 106 the inter-atomic distance is changed (and also the distance between atom layers of multi-layer two dimensional materials) which leads to a variation of the band gap. This relationship is explained by way of example for MoS₂ in FIGS. 2a and 2b.

FIG. 2a shows in a diagram a change of energy of the band gaps of multilayered MoS₂ in eV plotted over an interlayer distance increase in %. Thereby, a first curve 140 shows the indirect band gap (Δ(Σₘ−Γᵥ)), a second curve 142 (Δ(Kₘ−Kᵥ₁)) and a third curve 144 (Δ(Kₘ−Kᵥ₂)) show the direct band gaps].

FIG. 2b shows in a diagram a change of energy of the band gaps of MoS₂ in eV plotted over Mo—Mo distance (distance between molybdenum elements/atoms) variation in %. In FIG. 2b, the area below 0% indicates compressive strain, wherein the area above 0% indicates tensile strain. Thereby, a first curve 150 shows the indirect band gap (Δ(Σₘ−Γᵥ)), a second curve 152 (Δ(Kₘ−Kᵥ₁)) and a third curve 154 (Δ(Kₘ−Kᵥ₂)) show the direct band gaps].

MoS₂ and many other materials are available in mono and multilayer form. Thereby, the electronical structure also depends on the number of layers. Thus, by the choice of material and the choice of the number of layers it is also possible to optimize the gauge-factor towards the respective sensor application.

In the following table, direct and indirect band gaps of selected TMD-materials (TMD=transition metal dichalcogenides) and their dependence on layer thickness is illustrated:

| | Number of | | | Energy-level |
|---|---|---|---|---|
| Material | atomic layers | Band gap | | transition |
| MoS₂ | Volume-Material | ≈1.2 | eV | indirect |
| | | 1.29 | eV | indirect |
| | 6 | 1.37 | eV | indirect |
| | 5 | 1.4 | eV | indirect |
| | 4 | 1.45 | eV | indirect |
| | 3 | 1.35 eV-1.46 eV | | indirect |
| | 2 | 1.6 eV-1.65 eV | | indirect |
| | 1 | 1.8 | eV | direct |
| | | 1.89 | eV | direct |
| WS₂ | Volume-Material | 1.3 | eV | indirect |
| MoTe₂ | | 1.0 eV-1.13 eV | | indirect |
| MoSe₂ | | 1.1 | eV | indirect |
| | 1 | 1.55 | eV | direct |
| | | ≈1.58 | eV | direct |
| | | 1.49 | eV | direct |
| | 8 | ≈1.41 | eV | indirect |
| | 2 | 1.38 | eV | indirect |
| WS₂ | 2 | 1.95 | eV | indirect |
| WSe₂ | 1 | 1.61 | eV | direct |
| | 2 | 1.53 | eV | direct |
| | 3 | 1.45 | eV | indirect |
| | 4 | 1.42 | eV | indirect |
| | 8 | 1.37 | eV | indirect |
| WTe₂ | 1 | 0.71 | eV | direct |
| VSe₂ | 1 | Metallic | | — |
| CrS₂ | 1 | 0.93 | eV | direct |
| | 2 | 0.68 | eV | indirect |
| CrSe₂ | 1 | 0.74 | eV | direct |
| | 2 | 0.6 | eV | indirect |
| BP | Volume-Material | 0.3 | eV | indirect |

Besides, embodiments provide also the possibility to significantly reduce the size of the sensors while maintaining the same sensitivity as conventional sensors with silicon membranes. Thereby, a high integration density is enabled.

Embodiments use membranes of 2D materials (e.g., transition metal dichalcogenides) with high mechanical stability for the construction of mechanical sensors. By using a piezoresistive measurement principle, a high signal-to-noise ratio and thus a high sensitivity is achieved, due to the high gauge-factor of these materials. Further, by an appropriate choice of the material (band gap) the gauge-factor can be adapted to the specific requirements of the sensors.

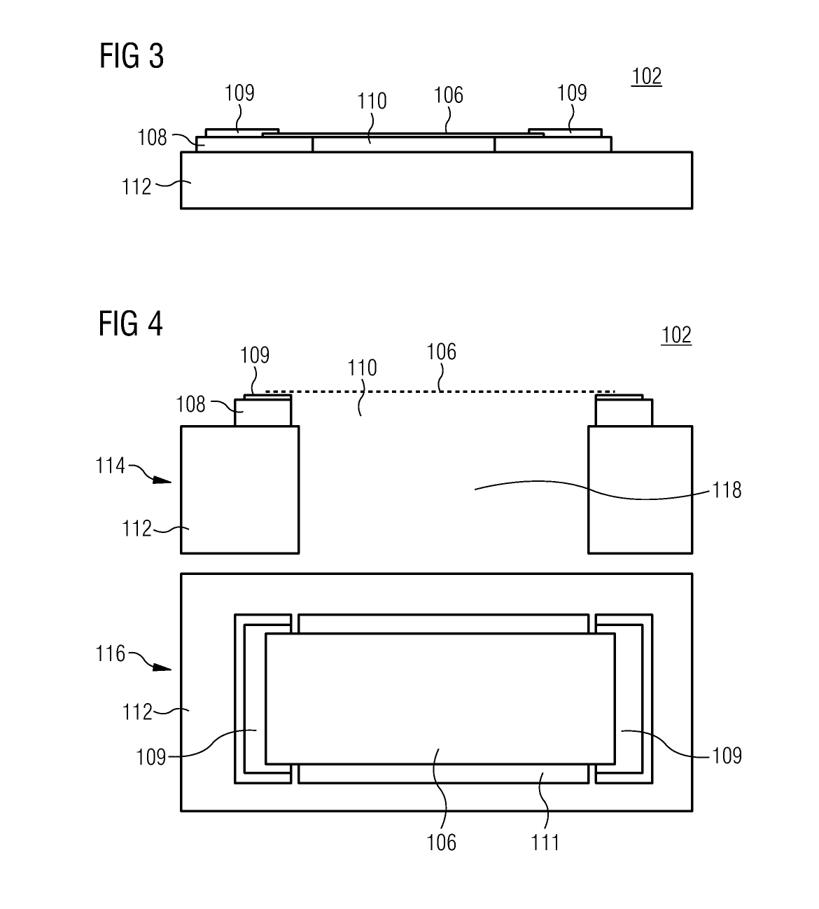

FIG. 3 shows a cross-sectional view of a MEMS device 102 according to an embodiment. The MEMS device 102 comprises a 2D material membrane 106, i.e. a membrane 106 of a material comprising a crystal structure with structural elements connected by covalent bonds in two dimensions only. The MEMS device 102 can further comprise a support 108 having a cavity 110 therethrough, wherein the membrane 106 extends over the support cavity 110. The support 108 can comprise a dielectric material, such as SiO₂. The support 108 can be, for example, a dielectric spacer.

The MEMS device 102 can further comprise (at least) two electrodes 109 contacting the membrane 106 on spaced apart positions. The detector circuit 104 (see FIG. 1) can be configured to detect/measure/evaluate the piezoresistive resistance of the material of the membrane 106 based on a signal present between the two electrodes 109.

Further, the MEMS device 102 can comprise a substrate 112, wherein the support 108 can be arranged on the substrate 112. As shown in FIG. 3, the support 108 can be arranged on the substrate 112 such that a volume defined by the support cavity 110 is hermetically sealed by the membrane 106, the support 108 and the substrate 112.

Thus, the MEMS device 112 shown in FIG. 3 can be a piezoresistive pressure sensor. In other words, FIG. 3 shows an implementation as a surface micromachined pressure sensor.

FIG. 4 shows a cross-sectional view 114 and a top view 116 of a MEMS device 102 according to an embodiment. In contrast to the MEMS device 102 shown in FIG. 3, the substrate 112 of the MEMS device 102 shown in FIG. 4 comprises a cavity 118 therethrough, wherein the support 108 is arranged on the substrate 112 such that the cavity 110 of the support 108 extends over the cavity 118 of the substrate 112.

Further, as indicated in the top view 116 of the MEMS device 102, the membrane 106 can be arranged on the support 108, such that the membrane 106 extends over the cavities 110 and 118 of the support 108 and the substrate 112, wherein an area of the membrane 106 which extends over the cavities 108 and 110 of the support 108 and the substrate 112 is smaller than an area of the cavity 110, such that ventilation slots 111 are formed on opposing sides of the membrane 106.

The MEMS device 102 shown in FIG. 4 is a piezoresistive microphone. The MEMS device 102 comprises a high signal-to-noise ratio due to the high gauge-factor and the high exibility/distensibility/elasticity of the material of the membrane 106. Further, compared to an electrostatic MEMS microphone, the piezoresistive MEMS microphone shown in FIG. 4 does not require a return/counter electrode and thus avoids the noise source caused thereby.

FIG. 5 shows a top view 120 of a MEMS device 102 and a schematic 122 of the control circuit 104, according to an embodiment. The MEMS device 102 comprises two membranes 106_1 and 106_2 and four electrodes 109_1 to 109_4, wherein first and second electrodes 109_1 and 109_2 of the four electrodes 109_1 to 109_4 contact a first membrane 106_1 of the two membranes 106_1 and 106_2 in spaced apart positions, and wherein third and fourth electrodes 109_3 and 109_4 of the four electrodes 109_1 to 109_4 contact a second membrane 106_2 of the two membranes 106_1 and 106_2 in spaced apart positions.

In embodiments, the detector circuit 104 can comprise a full bridge circuit as a differential read-out circuit for the MEMS device 102. The full bridge circuit comprises a first branch 126 and a second branch 128, wherein the piezoresistive resistance 130 of the first membrane 106_1 can be connected in series with a resistance 132 between a first terminal 134 and a second terminal 136 of the full bridge circuit, and wherein a resistance 134 and the piezoresistive resistance 136 of the second membrane 106_2 can be connected in series between the first terminal 134 and the second terminal 136 of the full bridge circuit.

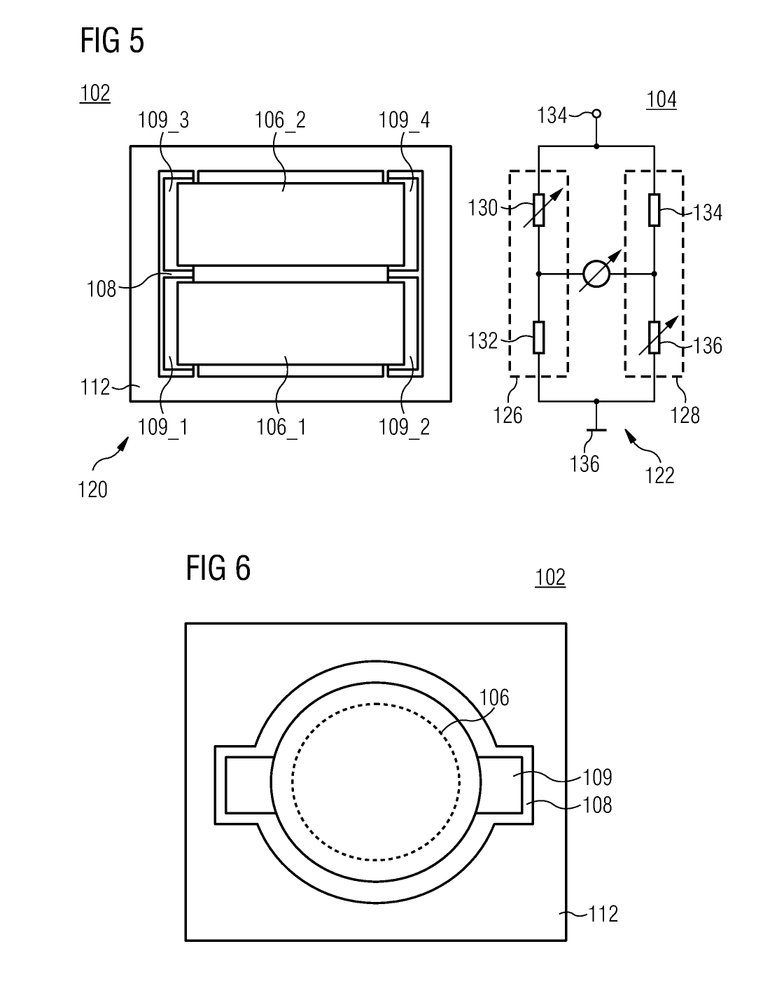

FIG. 6 shows a top view of a MEMS device 102 with a circular-shaped membrane 106, according to an embodiment. In other words, FIG. 6 shows an implementation of a circular shaped membrane 106 for piezoresistive read-out.

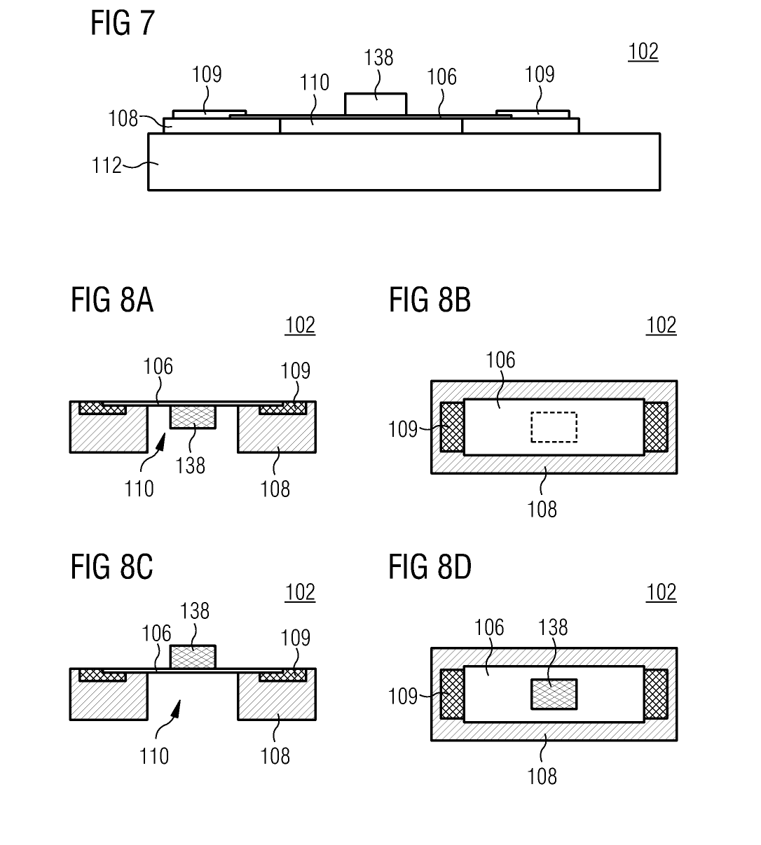

FIG. 7 shows a MEMS device 102 according to an embodiment. The MEMS device 102 comprises a membrane 106 and an inertial mass 138 attached to the membrane 106, wherein a material of the membrane 106 comprises a crystal structure with structural elements (unit cells) connected by covalent bonds in two dimensions only.

The material of the membrane 106 can be, for example, graphene or a transition metal chalcogenide, such as MoS₂, WS₂, MoTe₂, MoSe₂, WSe₂, WTe₂, VSe₂, CrS₂, CrSe₂, BP.

The MEMS device 102 can further comprise a support 108 having a cavity 110 therethrough, wherein the membrane 106 extends over the support cavity 110. Further, the MEMS device 102 can comprise a substrate 112, wherein the support 108 is arranged on the substrate 102.

The MEMS device 102 can further comprise two electrodes 109 contacting the membrane 106 on spaced apart positions. The detector circuit 104 (see FIG. 1) can be configured to detect/measure/evaluate the piezoresistive resistance of the material of the membrane 106 based on a signal present between the two electrodes 109.

The MEMS device 102 shown in FIG. 7 can be an inertial sensor. In other words, FIG. 7 shows an implementation as a surface micromachined inertial sensor.

FIG. 8a shows a cross-sectional view of a MEMS device 102, wherein FIG. 8b shows a top view of the MEMS device 102 shown in FIG. 8a. The MEMS device 102 comprises a membrane 106 that extends over the support cavity 110, and an inertial mass 138 attached to the membrane. As shown in FIG. 8a, the inertial mass 138 can be arranged on a bottom-side of the membrane 106, i.e. within the support cavity 110.

FIG. 8c shows a cross-sectional view of a MEMS device 102, wherein FIG. 8d shows a top view of the MEMS device 102 shown in FIG. 8c. In contrast to the MEMS device 102 shown in FIGS. 8a and 8b, in the MEMS device 102 shown in FIG. 8c the inertial mass is attached to the membrane 106 at a top-side of the membrane 106.

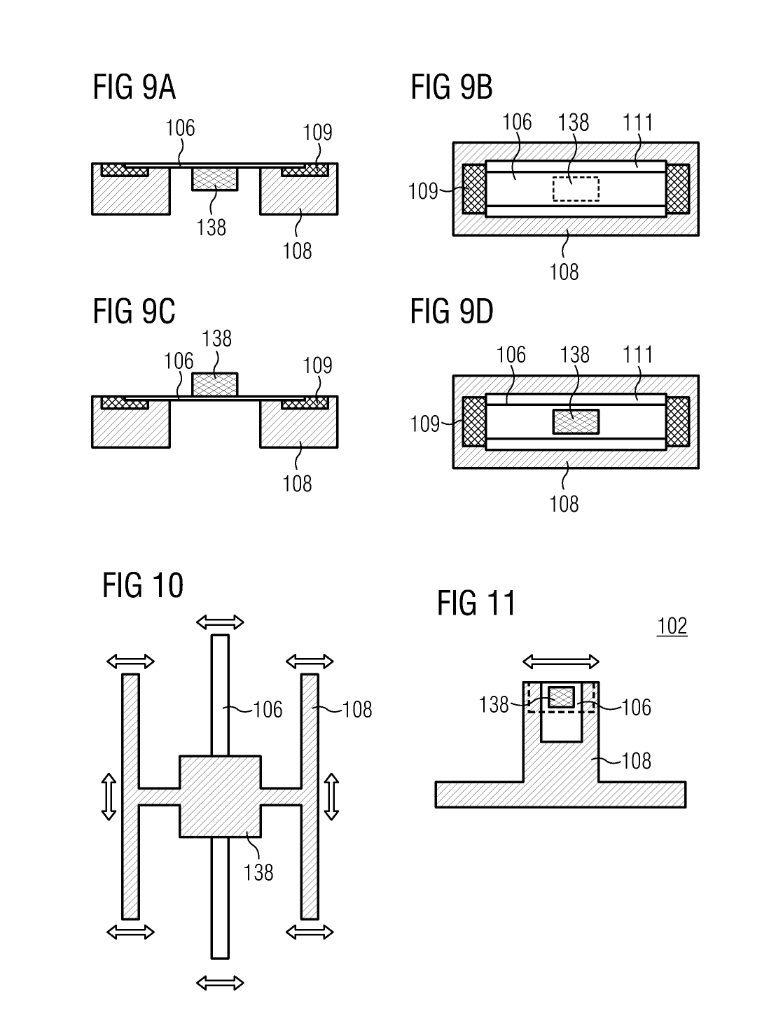

FIG. 9a shows a cross-sectional view of a MEMS device 102, wherein FIG. 9b shows a top view of the MEMS device 102 shown in FIG. 9a. Compared to the MEMS device 102 shown in FIGS. 8a and 8b, the area of the membrane 106 which extends over the support cavity 110 is smaller than an area of the cavity 110, such that ventilation slots 111 are formed on opposing sides of the membrane 106.

FIG. 9c shows a cross-sectional view of a MEMS device 102, wherein FIG. 9d shows a top view of the MEMS device 102 shown in FIG. 9c. In contrast to the MEMS device 102 shown in FIGS. 9a and 9b, in the MEMS device 102 shown in FIG. 9c the inertial mass 138 is attached to the membrane 106 at a top-side of the membrane 106.

FIG. 10 shows a top-view of a MEMS device 102, according to an embodiment. The MEMS device 102 comprises a support 108, a membrane 106 and an inertial mass 138 attached to the membrane 106. The MEMS device 102 shown in FIG. 10 can be a gyroscopic sensor. Thereby, the arrow indicates the measured axes of motion.

FIG. 11 shows a top-view of a MEMS device 102, according to an embodiment. The MEMS device 102 comprises a support 108, a membrane 106 and an inertial mass 138 attached to the membrane 106. The MEMS device 102 shown in FIG. 11 can be a tuning fork type gyroscopic sensor. Thereby, the arrows indicate measured axis of motion.

Embodiments provide size reduction together with performance increase and the possibility to integrate MEMS with ICs, which are features that are crucial for many MEMS sensor products. Graphene MEMS may also enable the use of polymers instead of silicon as structural MEMS device material, without compromising sensor performance.

Embodiments provide electromechanical pressure sensing using the piezoresistive effect in suspended mono-layer graphene membranes.

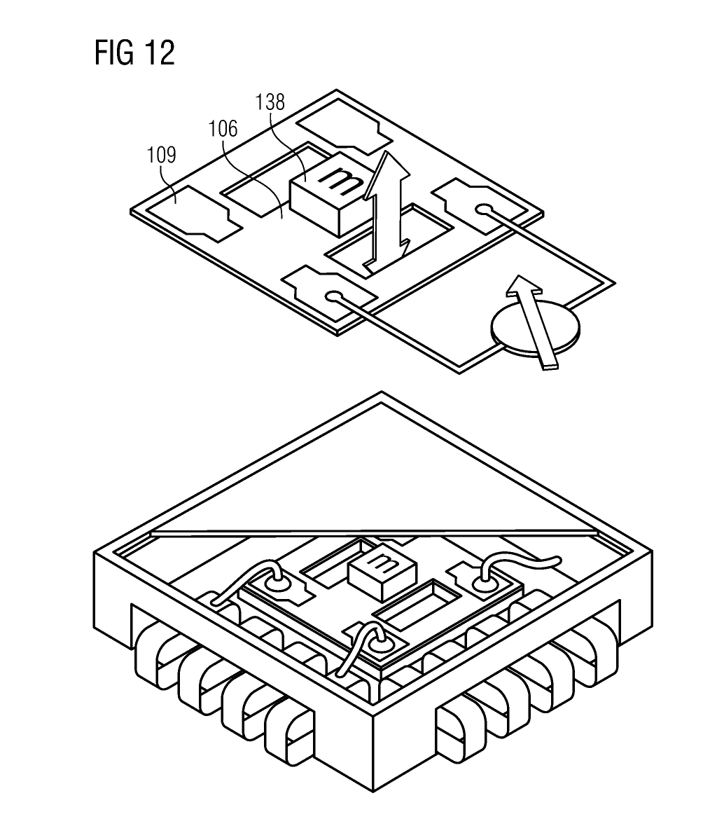

FIG. 12 shows an accelerometer design, according to an embodiment, wherein FIGS. 8a to 9d show details of implemented accelerometer designs, and wherein FIGS. 10 and 11 show examples of related gyroscope designs that are based on electromechanical sensing in graphene membranes. Thereby, reference numerals 106 depicts graphene membrane patches, reference numeral 108 depicts supports, and reference numeral 138 depicts seismic masses attached to the graphene membranes. Reference numeral 109 depicts electrical contact to the graphene patches that allow to measure the resistance change of the graphene as a result of strain/deflections in the graphene. There may be more than two electrical contacts to the graphene patches to provide more accurate measurements. Also reference graphene patches may be included that do not contain seismic masses or that are attached to the substrate (non-suspended) to provide reference signals that can compensate the measurement signal for noise, temperature effects etc.

The support (e.g., a substrate) 108, containing cavities or holes typically consist of patterned silicon, plastic, ceramic, metal or other material substrates. The substrate may also contain integrated circuits such as CMOS-based for the sensor readout signal. Furthermore, the sensors may be packaged inside cavities containing vacuum or inert gas atmospheres. The sealing may be on chip (e.g. FIG. 12) or on wafer-level or based on bonding a lid towards the substrate onto which the graphene transducer is placed (bonding can take place towards one or both sides of the substrate).

Monolayer graphene consists of sp²-bonded carbon atoms arranged in a dense honeycomb crystal structure. It exhibits exceptional electronic and mechanical properties, including high carrier mobility, a high Young's modulus of about 1 TPa, stretchability of up to approximately 20% and near impermeability for gases. These properties make graphene a very promising material for different types of electronic and sensor applications. Graphene MEMS sensors have the potential to dramatically reduce device dimensions and costs, while providing improved sensitivities as compared to the state-of-the-art MEMS sensors that are currently used, e.g. in smartphones for interacting with the user in novel ways.

Embodiments use the piezoresistive effect from uniaxial strain in suspended mono-layer graphene membranes for electromechanical sensing. In contrast to that, conventional sensors use the electric field effect in graphene for electromechanical sensing. Experiments showed that the use of the piezoresistive effect in ultrathin graphene membranes for MEMS sensors enables unprecedented sensitivity per unit area and thus is an enabling approach for novel graphene-based MEMS sensors with substantially improved performance. Graphene layer transfer and integration techniques are critical methods for implementing novel graphene-based MEMS devices.

Experimental results show that MEMS pressure sensors using the piezoresistive effect in suspended graphene membranes achieve unprecedented sensitivity per unit area. This is the case, despite the moderate piezoresistive gauge factor of 3 to 4 observed in graphene (typical gauge factors in silicon range from −140 to 200). The extraordinarily high sensitivity (AR/R) can be explained because the sensitivity of a membrane-based piezoresistive sensor is strongly dependent on the membrane thickness as can be seen from Eq. 1. Eq. 1 is valid for squared membranes that are deflected by differential pressure, and for membrane deflections that are large compared to the membrane thickness, where P is the differential pressure, E is the Young's modulus of the membrane material, a² is the membrane area and h is the membrane thickness.

Suspended graphene membranes are resilient and only one atom layer thick (˜0.35 nm), which is several orders of magnitude thinner than the membrane thickness of typical silicon-based MEMS sensors today (˜300-3000 nm). Eq. 1 indicates that graphene membranes may enable sensitivity increases per unit area in the range of two orders of magnitude. This makes graphene a very promising material for electromechanical transduction in emerging MEMS, including the inertial sensors like accelerometers and gyroscopes as outlined in the figures above.

The sensors can be implemented using various graphene donor substrates.

Embodiments provide accelerometer concepts based on electromechanical transduction in suspended graphene membranes (see FIG. 12).

Embodiments can be integrated based on graphene layer transfer for suspended graphene membranes into silicon MEMS structures.

Embodiments provide refined accelerometer concepts based on electromechanical transduction in suspended graphene membranes. The vibration in the actuation axis will most likely be achieved by silicon beam while the sensing axis will make use of a graphene membrane.

Embodiments can be integrated based on graphene layer transfer for suspended graphene membranes into 3D patterned polymer MEMS structures.

Embodiments provide a fully packaged accelerometer as depicted in the lower part of FIG. 12 that is based on electromechanical transduction in suspended graphene membranes.

Embodiments allow an integration of a graphene accelerometer design directly onto a commercial off-the-shelve silicon integrated circuit (IC) die for sensor signal readout.

Embodiments provide gyroscope concepts based on electromechanical transduction in suspended graphene membranes.

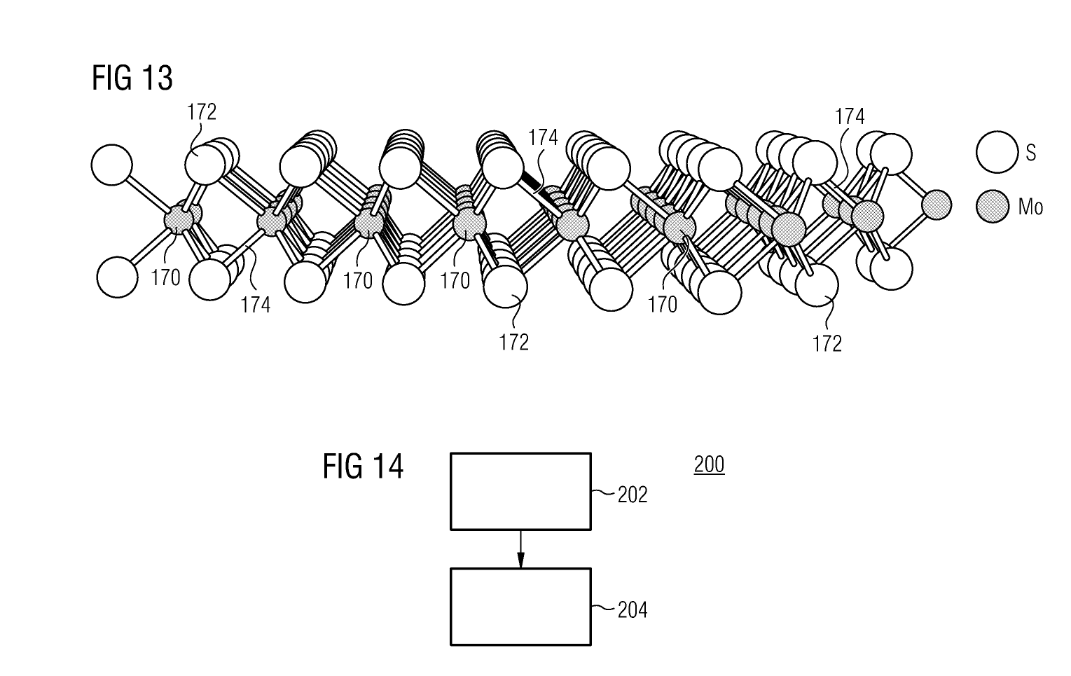

FIG. 13 shows an illustrative view of a material of the membrane, according to an embodiment. The material of the membrane comprises a crystal structure with structural elements (unit cells) connected by covalent bonds in two dimensions only. As shown in FIG. 13, the structural elements of the material of the membrane can comprise a three dimensional structure, however, the structural elements are connected to each other by covalent bonds in two dimensions only. In detail, FIG. 13 shows a monolayer of MoS₂, wherein Mo is indicated with reference numeral 170, S₂ is indicated with reference numeral 172, and wherein the covalent bonds are indicated with reference numeral 174.

FIG. 14 shows a flowchart of a method 200 for manufacturing a MEMS 100 comprising a MEMS device 102 and a detector circuit 104. The method 200 comprises a step 202 of providing a membrane 106 of the MEMS device 102, wherein a material of the membrane 106 comprises a band gap and a crystal structure with structural elements (unit cells) connected by covalent bonds in two dimensions only, and a step 204 of providing a detector circuit 104 configured to determine a deformation of the membrane 106 based on a piezoresistive resistance of the material of the membrane 106.

In embodiments, the step 202 of providing the membrane 106 can comprise depositing (e.g., via a chemical vapor deposition (CVD) or physical vapor deposition (PVD)) a metal (e.g., Mo or W) or metal oxide (e.g., WO₂) and providing gaseous sulfur or selenium at a temperature of 400° C. or higher, such that the gaseous sulfur or selenium reacts with the metal or metal oxide, in order to obtain a chalcogenide (e.g., MoS₂ or WSe₂).

Further, in embodiments, the step 202 of providing the membrane 106 can comprise depositing (e.g., via a chemical vapour deposition (CVD) or plasma enhanced chemical vapour deposition (PECVD)) a gaseous transfer metal (e.g., WF₆, MoF₆, MoCl₅) and a chalcogen precursor (e.g., S, Se, H₂S, H₂Se).

Further, in embodiments, the step 202 of providing the membrane 106 can comprise depositing the material of the membrane using molecular beam epitaxy.

Further, in embodiments, the step 202 of providing the membrane 106 can comprise depositing the material of the membrane using atomic layer deposition (ALD) and precursors (e.g., WF₆, MoF₆, MoCl₅, S, H₂S, H₂Se). Thereby, the atomic layer deposition is self-limiting and enables a good layer control.

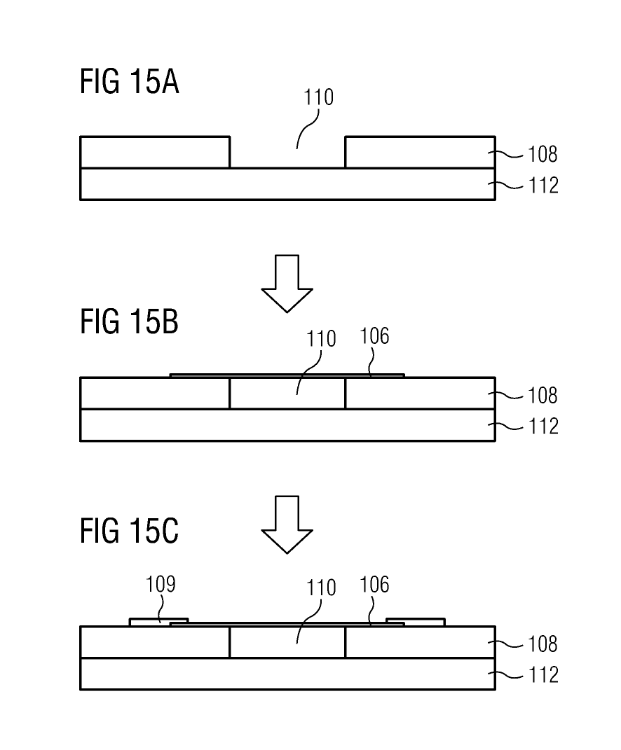

In the following, embodiments of a method for manufacturing the MEMS device 102 (e.g., sensor or structure) are described by way of example with regards to FIGS. 15a to 17c.

FIG. 15a-c show cross-sectional views of the MEMS device 102 after different steps of a transfer based manufacturing method. In detail, FIG. 15a shows a cross-sectional view of the MEMS device 102 after providing a substrate 112 and a support 108, wherein the support 108 comprises a cavity 110 therethrough. FIG. 15b shows a cross-sectional view of the MEMS device 102 after transferring the 2D material membrane 106 onto the support 108 such that the membrane 106 extends over the support cavity 110, and structuring the 2D membrane 106. FIG. 15c shows a cross-sectional view of the MEMS device 102 after depositing metal contacts 109 on the support 108 and membrane 106, and structuring the metal contacts 109 such that the metal contacts 109 contact the membrane 106 on spaced apart positions.

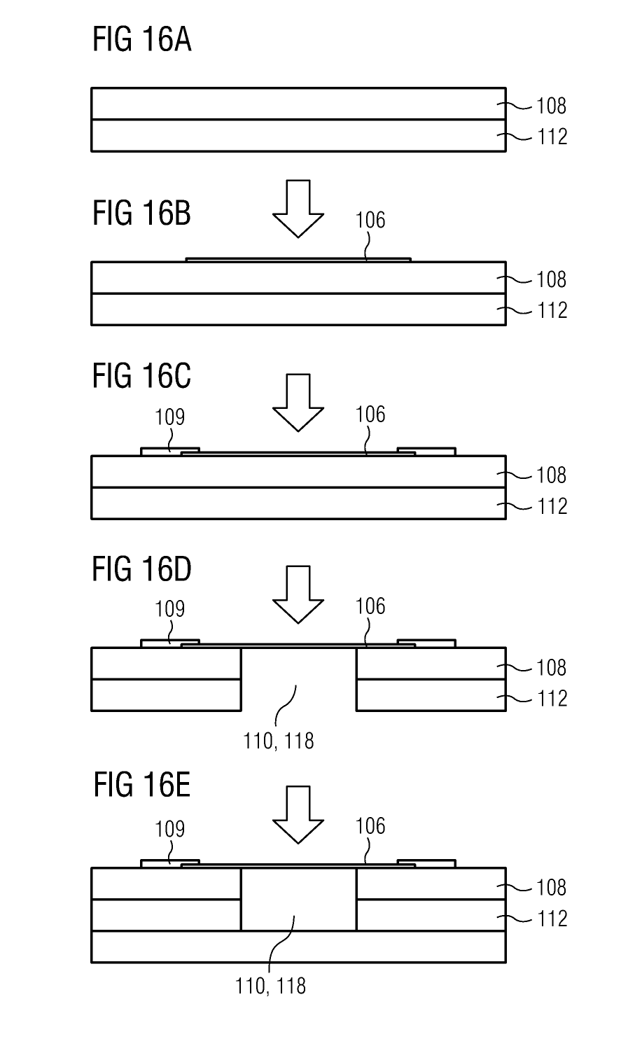

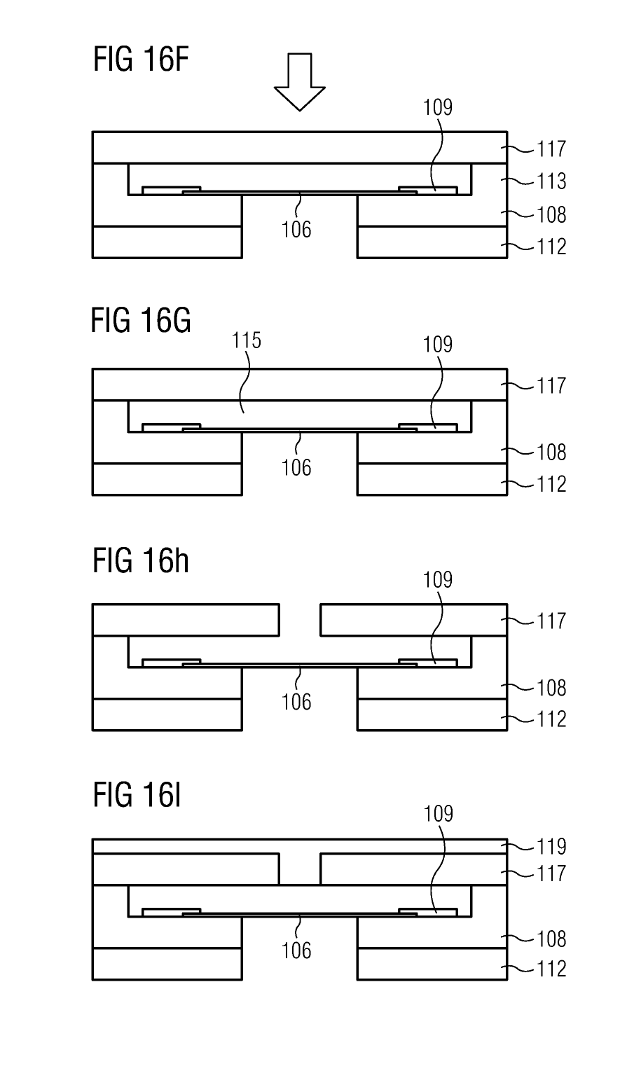

FIGS. 16a-i show cross-sectional views of the MEMS device 102 after different steps of a direct deposition based manufacturing method. In detail, FIG. 16a shows a cross-sectional view of the MEMS device 102 after providing a substrate 112 and a support layer 108 arranged on the substrate 112. FIG. 16b shows a cross-sectional view of the MEMS device 102 after depositing and structuring the 2D material membrane 106. FIG. 16c shows a cross-sectional view of the MEMS device 102 after depositing metal contacts on the support layer 108 and the membrane 106, and structuring the metal contacts 109 such that the metal contacts contact the membrane 106 on spaced apart positions. FIG. 16d shows a cross-sectional view of the MEMS device 102 after a backside etch of the substrate 112 and the support layer 108 up to the membrane 106 (to the 2D material selective substrate etching) such that the substrate 112 and the support 108 comprise cavities 110, 118 therethrough and the membrane 106 is exposed. FIG. 16e shows a cross-sectional view of the MEMS device 102 after encapsulating the cavities 110, 118 below the membrane 106 by means of backside wafer bonding.

Alternative to FIG. 16e, FIG. 16f shows a cross-sectional view of the MEMS device 102 after encapsulating a cavity on the top-side of the membrane 106 by a spacer 113 and front-side wafer bonding of a cap layer 117.

Further, alternative to FIGS. 16e and 16f, FIG. 16g shows a cross-sectional view of the MEMS device 102 after depositing a sacrificial material 115 onto the membrane 106 and a cap layer 117 thereon. FIG. 16h shows a cross-sectional view of the MEMs device 102 after etching a cavity above the membrane via a hole in the cap layer 117. FIG. 16i shows a cross-sectional view of the MEMS device 102 after closing/sealing the hole in the cap layer 117 by depositing a material, e.g. via chemical vapor deposition (CVD).

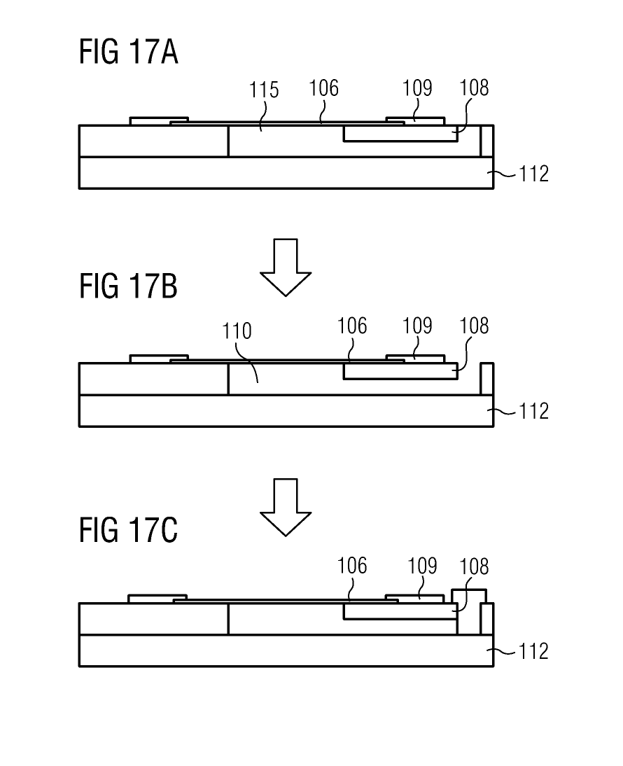

FIGS. 17a-c show cross-sectional views of the MEMS device 102 after different direct deposition based manufacturing steps. In detail, FIG. 17a shows a cross-sectional view of the MEMS device 102 after providing a substrate 112 with a partial sacrificial layer 115, and a support 108 partly arranged on the substrate 112 and partly arranged on the sacrificial layer 115, depositing the 2D material membrane 106 on the support 108, depositing metal contacts 109 on the support 108 and the membrane 106, and structuring the metal contacts 109 such that the metal contacts 109 contact the membrane 109 on spaced apart positions. FIG. 17b shows a cross-sectional view of the MEMS device 102 after etching the cavity 110 below the membrane 106 via a hole in the substrate. FIG. 17c shows a cross-sectional view of the MEMS device 102 after closing/sealing the hole in the substrate via chemical vapor deposition (CVD).

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, some one or more of the most important method steps may be executed by such an apparatus.

The above described embodiments are merely illustrative for the principles of the present invention. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

1. A MEMS, comprising:
a MEMS device comprising a membrane, wherein a material of the membrane comprises a band gap and a crystal structure with structural elements connected by covalent bonds in two dimensions only; and
a detector circuit configured to determine a deformation of the membrane based on a piezoresistive resistance of the material of the membrane.

2. The MEMS according to claim 1, wherein the material of the membrane is a transition metal chalcogenide.

3. The MEMS according to claim 1, wherein the material of the membrane is one out of MoS₂, WS₂, MoTe₂, MoSe₂, WSe₂, WTe₂, VSe₂, CrS₂, CrSe₂, BP.

4. The MEMS according to claim 1, wherein the MEMS device comprises a support having a cavity therethrough, wherein the membrane extends over the support cavity.

5. The MEMS according to claim 4, wherein the support is a dielectric spacer.

6. The MEMS according to claim 4, wherein the MEMS device comprises a substrate, wherein the support is arranged on the substrate.

7. The MEMS according to claim 6, wherein the substrate comprises a cavity therethrough, wherein the support is arranged such that the cavity of the support extends over the cavity of the substrate.

8. The MEMS according to claim 1, wherein the MEMS device comprises an inertial mass attached to the membrane.

9. The MEMS according to claim 1, wherein the MEMS device comprises two electrodes contacting the membrane on spaced apart positions, wherein the detector circuit is configured to detect the piezoresistive resistance of the material of the membrane based on a signal present between the two electrodes.

10. A MEMS, comprising:
a MEMS device comprising a membrane and an inertial mass attached to the membrane, wherein a material of the membrane comprises a crystal structure with structural elements connected by covalent bonds in two dimensions only; and
a detector circuit configured to determine an acceleration or rotation rate of the inertial mass based on a piezoresistive resistance of the material of the membrane.

11. The MEMS according to claim 10, wherein the material of the membrane is graphene or a transition metal chalcogenide.

12. A Method for manufacturing a MEMS comprising a MEMS device and a detector circuit, the method comprising:
providing a membrane of the MEMS device, wherein a material of the membrane comprises a band gap and a crystal structure with structural elements connected by covalent bonds in two dimensions only; and
providing a detector circuit configured to determine a deformation of the membrane based on a piezoresistive resistance of the material of the membrane indicative.

13. The method according to claim 12, wherein providing the membrane comprises:
depositing a metal or metal oxide; and
providing gaseous sulfur or selenium at a temperature of 400° C. or higher, such that the gaseous sulfur or selenium reacts with the metal or metal oxide, in order to obtain a chalcogenide.

14. The method according to claim 12, wherein providing the membrane comprises:
depositing a gaseous transfer metal and a chalcogen precursor.

15. The method according to claim 12, wherein providing the membrane comprises:
depositing the material of the membrane using molecular beam epitaxy.

16. The method according to claim 12, wherein providing the membrane comprises:
depositing the material of the membrane using atomic layer deposition and precursors.
